(19) United States
(12) Patent Application Publication
(10) Pub. No.: US 2015/0262889 A1
(43) Pub. Date: Sep. 17, 2015

(54) METHOD FOR MANUFACTURING SEMICONDUCTOR DEVICE

(71) Applicant: Kabushiki Kaisha Toshiba, Tokyo (JP)

(72) Inventors: Atsuko Yamashita, Himeji Hyogo (JP); Yoichi Hori, Himeji Hyogo (JP); Takao Noda, Himeji Hyogo (JP); Hiroshi Kono, Himeji Hyogo (JP)

(21) Appl. No.: 14/465,539

(22) Filed: Aug. 21, 2014

(30) Foreign Application Priority Data
Mar. 14, 2014 (JP) 2014-052792

(51) Int. Cl. H01L 21/66; H01L 29/66

(52) U.S. Cl. CPC H01L 22/12; H01L 29/66143

(57) ABSTRACT

According to one embodiment, a method for manufacturing a semiconductor device, including: detecting whether or not a defect being present in a wafer substrate and obtaining coordinate information of the defect; and determining positions of a first disposal region and a second disposal region in a semiconductor chip region based on the coordinate information so that the defect falls in the first disposal region in disposing in a plane of the semiconductor chip region having the first disposal region on which a first diode having a first conductivity type region and a second conductivity type region being disposed and the second disposal region on which a second diode having a metal film and a semiconductor region contacting the metal film being disposed.

### CROSS-REFERENCE TO RELATED APPLICATIONS

This application is based upon and claims the benefit of priority from Japanese Patent Application No.2014-052792, filed on Mar. 14, 2014; the entire contents of which are incorporated herein by reference.

### FIELD

Embodiments described herein relate generally to a method for manufacturing a semiconductor device.

### BACKGROUND

Schottky diodes use an energy barrier formed between an electrode film provided on a substrate surface and a substrate.

Because of this, when a defect is present in a silicon carbide wafer, and, in particular, there is a defect on a wafer substrate surface, the Schottky diodes cannot be formed in these regions. Therefore, when forming the Schottky diodes on the silicon carbide wafer, there is a need to form the Schottky diodes so as to avoid the defect.

However, if the Schottky diodes are disposed so as to avoid the defect, a chip area that can be taken out from the wafer substrate is decreased and a manufacturing yield of a semiconductor device is decreased.

### BRIEF DESCRIPTION OF THE DRAWINGS

FIG. 1 is a flow illustrating a manufacturing method of a semiconductor device according to an embodiment;

FIG. 2A is a schematic plan view illustrating the silicon carbide substrate according to the embodiment, and FIG. 2B is a schematic view illustrating an in-plane distribution of the defect present in the silicon carbide substrate;

FIG. 3 is a schematic plan view illustrating a semiconductor chip region lined up in the silicon carbide substrate according to the embodiment; and

FIG. 4 is a schematic plan view illustrating a state of exposure being performed on the silicon carbide substrate according to the embodiment.

### DETAILED DESCRIPTION

According to one embodiment, a method for manufacturing a semiconductor device, including: detecting whether or not a defect being present in a wafer substrate and obtaining coordinate information of the defect; and determining positions of a first disposal region and a second disposal region in a semiconductor chip region based on the coordinate information so that the defect falls in the first disposal region in disposing in a plane of the semiconductor chip region having the first disposal region on which a first diode having a first conductivity type region and a second conductivity type region being disposed and the second disposal region on which a second diode having a metal film and a semiconductor region contacting the metal film being disposed.

Hereinafter, embodiments will be described below with reference to the drawings. In the following description, the same reference numeral is applied to the same member, and for members that have been described once, the description is omitted as appropriate.

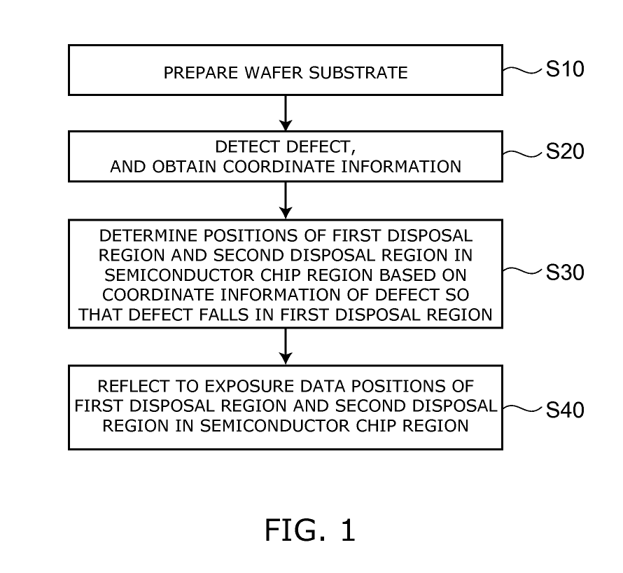

FIG. 1 is a flow illustrating a manufacturing method of a semiconductor device according to an embodiment.

First, a silicon carbide substrate in a wafer state is prepared (step S10).

A plurality of semiconductor chip regions forming a semiconductor chip can be disposed on this silicon carbide substrate. The semiconductor chip is, for example, a semiconductor chip provided with a diode. Each of the plurality of semiconductor chip regions has a first disposal region and a second disposal region.

In the first disposal region, a PIN diode (first diode) having a p-type region (first conductivity type region) and an n-type region (second conductivity type region) is disposed. In the second disposal region, a Schottky diode (second diode) having a metal film and a semiconductor region contacting with the metal film is disposed. The Schottky diode may be a diode of a junction barrier Schottky (JBS) type.

Next, a defect present in the silicon carbide substrate is detected, and coordinate information thereof is obtained (step S20). For example, the defect is searched for by a laser scattering method by irradiating a laser beam on a surface of the silicon carbide substrate.

Next, if the defect is present in the silicon carbide substrate, based on the coordinate information of the defect, positions of the first disposal region and the second disposal region in the semiconductor chip region are determined so that the defect falls in the first disposal region (step S30).

Next, the positions of the first disposal region and the second disposal region in the semiconductor chip region are reflected to exposure data (step S40).

The flow described above will be described more specifically.

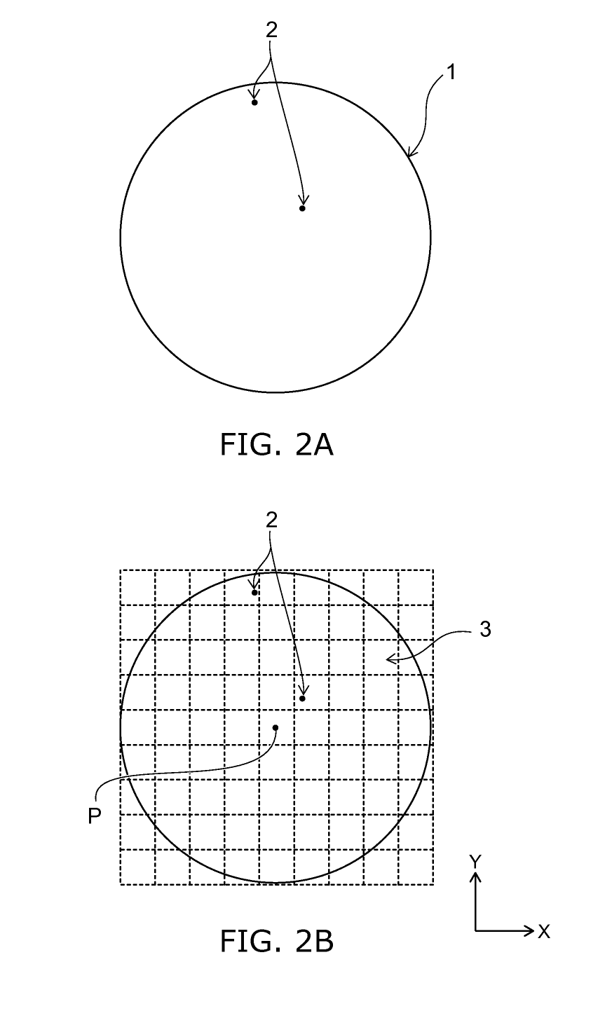

FIG. 2A is a schematic plan view illustrating the silicon carbide substrate according to the embodiment, and FIG. 2B is a schematic view illustrating an in-plane distribution of the defect present in the silicon carbide substrate.

A silicon carbide substrate 1 illustrated in FIG. 2A is prepared. In the silicon carbide substrate 1, normally, a defect 2 (surface defect) such as a defect based on a downfall, a defect generated in epitaxial growth, or a triangular defect is randomly present.

When seeking a position of the defect 2, a surface of the silicon carbide substrate 1 is divided into a plurality of regions 3 lined up in an X-direction (first direction) or a Y-direction (second direction) intersecting the X-direction in a plane of the silicon carbide substrate 1 in advance. Here, an arbitrary reference point P in the silicon carbide substrate 1 is determined.

Subsequently, the position of the defect 2 (for example, coordinates) from the reference point Pin each of the plurality of the regions 3 is sought by the laser scattering method. By this, the in-plane distribution of the defect 2 present in the silicon carbide substrate 1 is found. Data of this in-plane distribution is stored in a measuring instrument for detecting a defect and in an exposure device. Moreover, based on this in-plane distribution, it is determined in which position the PIN diode (first disposal region) is disposed or in which position the Schottky diode (second disposal region) is disposed in the semiconductor chip region. In allocating disposal, the most efficient disposal is determined, and positions of individual semiconductor chip regions are determined. Allocation of disposal is reflected as the exposure data.

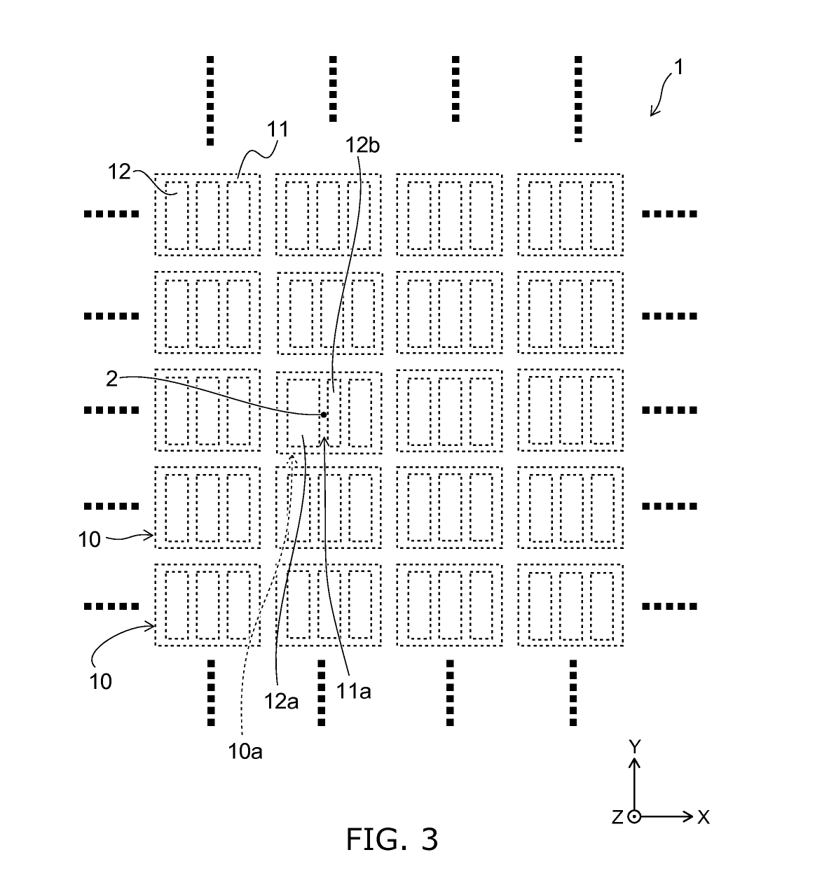

FIG. 3 is a schematic plan view illustrating a semiconductor chip region lined up in the silicon carbide substrate according to the embodiment.

In FIG. 3, a plurality of semiconductor chip regions 10 provided in the silicon carbide substrate 1 lined up in the X-direction and the Y-direction is illustrated (broken lines in the drawing). The semiconductor chip region 10 has a first disposal region 11 in which the PIN diode is disposed and a second disposal region 12 in which the Schottky diode is disposed.

In FIG. 3, as an example, three second disposal regions 12 and the first disposal region 11 surrounding these three second disposal regions 12 are illustrated in the semiconductor chip region 10, but the embodiment is not limited to this number. That is, in each of the plurality of semiconductor chip regions 10, at least one first disposal region 11 and at least one second disposal region 12 are respectively disposed. Moreover, in order to impart a surge resistance to the semiconductor chip, the first disposal region 11 and the second disposal region 12 are disposed so that a number of the second disposal regions 12 is greater than a number of the first disposal regions 11.

Here, a surge is, for example, an electrical characteristic for ensuring reliability so that the diode is not destroyed when a sudden current or voltage enters. Therefore, by disposing so that the number of the second disposal regions 12 is greater than the number of the first disposal regions 11, the surge resistance can be increased while maintaining a function in normal operation.

If the defect 2 is detected, for disposal in the semiconductor chip region 10, as described above, a position of any one of the plurality of semiconductor chip regions 10 is determined so that the position of the defect 2 falls in the first disposal region 11 of the PIN diode. In FIG. 3, the reference numeral “10a” is applied to this one semiconductor chip region 10.

For example, in a semiconductor chip region 10a, an area of a second disposal region 12a is larger and an area of a second disposal region 12b is smaller compared to those of the other semiconductor chip regions 10. Moreover, a region 11a in the first disposal region 11 sandwiched between the second disposal region 12a and second disposal region 12b is shifted to the position where the defect 2 is present. Next, the positions of this first disposal region and this second disposal region are reflected to the exposure data.

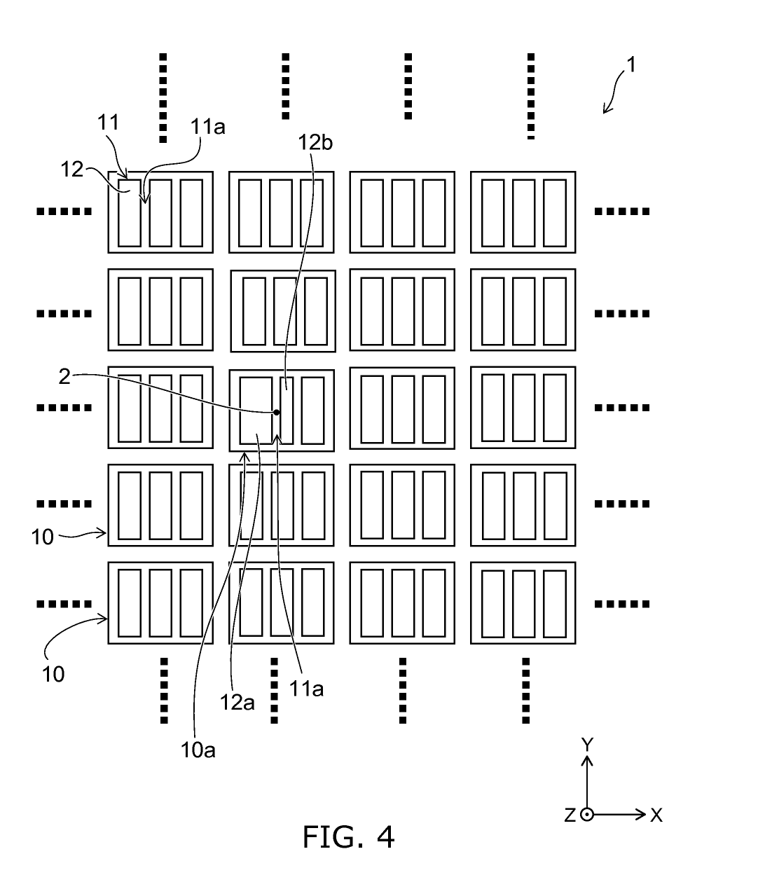

FIG. 4 is a schematic plan view illustrating a state of exposure being performed on the silicon carbide substrate according to the embodiment.

Subsequently, when carrying out exposure on the silicon carbide substrate 1, a reticle mask corresponding to the semiconductor chip region 10 is used and a pattern of each of the plurality of semiconductor chip regions 10 is transferred onto the silicon carbide substrate 1 (solid line in the drawing). In pattern transferring, for example, light shooting of one line is performed along the Y-direction, and after light shooting of this line is performed, light shooting of one line next to this line is performed. This operation is repeated sequentially.

Exposure is performed for each semiconductor chip region 10 based on the exposure data described above.

After this exposure is finished, a wafer process such as etching or film formation is continuously performed on the silicon carbide substrate 1. Moreover, a termination region or the like and an electrode or the like are formed.

Conventionally, if the defect 2 is accidentally present in a location where the Schottky diode is disposed, the semiconductor chip separated by a dicing process is handled as a defective product ex-post facto.

In contrast, in the embodiment, even if the defect 2 is present in the silicon carbide substrate 1, the PIN diode is disposed where the defect 2 is present. Moreover, the Schottky diode is disposed so as to avoid the defect 2.

That is, even if the defect is present on the wafer substrate surface, a PN-type diode can be disposed without problems in a position where the defect is present if the PN-type diode is such that a PN junction is positioned in a deep position from the wafer substrate surface. By this, semiconductor chips handled as defective products are reduced and the manufacturing yield of the semiconductor device is improved.

Therefore, even if a surge resistance of the PN-type diode is comparatively weak, a semiconductor device having a high surge resistance is formed by disposing, with regard to the number of Schottky diodes and the number of PIN-type diodes, more of the former than the latter. Note that, in addition to the diode, a MOSFET, an IGBT, or the like may be installed in the semiconductor chip region 10a.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, comprising:
detecting whether or not a defect being present in a wafer substrate and obtaining coordinate information of the defect; and
determining positions of a first disposal region and a second disposal region in a semiconductor chip region based on the coordinate information so that the defect falls in the first disposal region in disposing in a plane of the semiconductor chip region having the first disposal region on which a first diode having a first conductivity type region and a second conductivity type region being disposed and the second disposal region on which a second diode having a metal film and a semiconductor region contacting the metal film being disposed.

2. The method according to claim 1, wherein, when seeking a position of the defect, the position of the defect is sought from a reference point in the wafer substrate and an in-plane distribution of the defect in the plane of the wafer substrate is sought.

3. The method according to claim 2, wherein the position of the first disposal region is determined based on the in-plane distribution.

4. The method according to claim 1, further comprising reflecting the positions of the first disposal region and the second disposal region in the semiconductor chip region to exposure data, and performing exposure for the semiconductor chip region.

5. The method according to claim 2, further comprising reflecting the positions of the first disposal region and the second disposal region in the semiconductor chip region to exposure data and performing exposure for the semiconductor chip region.

6. The method according to claim 3, further comprising reflecting the positions of the first disposal region and the second disposal region in the semiconductor chip region to exposure data and performing exposure for the semiconductor chip region.

7. The method according to claim 1, wherein at least one first disposal region and at least one second disposal region are respectively disposed in the semiconductor chip region, and a number of the second disposal regions is greater than a number of the first disposal regions.

8. The method according to claim 2, wherein at least one first disposal region and at least one second disposal region are respectively disposed in the semiconductor chip region, and a number of the second disposal regions is greater than a number of the first disposal regions.

9. The method according to claim 3, wherein at least one first disposal region and at least one second disposal region are respectively disposed in the semiconductor chip region, and a number of the second disposal regions is greater than a number of the first disposal regions.

10. The method according to claim 4, wherein at least one first disposal region and at least one second disposal region are respectively disposed in the semiconductor chip region, and a number of the second disposal regions is greater than a number of the first disposal regions.

11. The method according to claim 1, wherein a silicon carbide substrate is used as the wafer substrate.

12. The method according to claim 1, wherein the position of the defect is sought using a laser scattering method.
